(19) United States
(12) Patent Application Publication
(10) Pub. No.: US 2017/0215287 A1
(43) Pub. Date: Jul. 27, 2017

(54) FOLDABLE MEMORY CARTRIDGE

(71) Applicant: HEWLETT PACKARD ENTERPRISE DEVELOPMENT LP, Houston, TX (US)

(72) Inventors: Paul E. WESTPHALL, Tomball, TX (US); Minh H. NGUYEN, Katy, TX (US); Martha GOMEZ, Houston, TX (US)

(21) Appl. No.: 15/329,577

(22) PCT Filed: Sep. 10, 2014
(86) PCT No.: PCT/US2014/055002

§ 371 Date: Jan. 27, 2017

(51) Int. Cl. H05K 1/14; H05K 7/14

(52) U.S. Cl. CPC H05K 1/148; H05K 7/1487; H05K 7/1461; H05K 2201/10159

(57) ABSTRACT

A memory cartridge includes a first printed circuit board and a second printed circuit board. The first printed circuit board includes a DIMM connectors to receive a first set of DIMMS. The second printed circuit board includes a second set of DIMM connectors to receive a second set of DIMMS. The first printed circuit board and the second printed circuit board are movably connected to each other to enable the first printed circuit board and the second printed circuit board to fold over each other.

### BACKGROUND

Memory cartridges are removably inserted into slots of a chassis such as a server system. The memory cartridges include electronic devices such as dual inline memory modules powered by and in communication with the server system when memory cartridges are inserted into the slots of the chassis.

### BRIEF DESCRIPTION OF THE DRAWINGS

Non-limiting examples are described in the following description, read with reference to the figures attached hereto and do not limit the scope of the claims. Dimensions of components and features illustrated in the figures are chosen primarily for convenience and clarity of presentation and are riot necessarily to scale. Referring to the attached figures:

FIG. 1 is a block diagram illustrating a memory cartridge according to an example.

FIG. 2A is a perspective view illustrating a memory cartridge in an open state without dual inline memory modules (DIMMS) installed thereon according to an example.

FIG. 2B is a perspective view illustrating a memory cartridge in an open state with DIMMS installed thereon according to an example.

FIG. 3A is a perspective view illustrating the memory cartridge of FIG. 2B in a closed state according to an example.

FIG. 3B is a cross sectional view of the memory cartridge of FIG. 3A according to an example.

FIG. 4 is a block diagram illustrating a removable dual minor cartridge according to an example.

FIG. 5 is a perspective view illustrating a server system with a plurality of removable dual memory cartridges installed therein according to an example.

FIG. 6A is a perspective view illustrating a respective removable dual memory cartridge of FIG. 4 according to an example.

FIG. 6B is a cross-sectional view of the respective removable dual memory cartridge of FIG. GA according to an example.

FIG. 7 is a flowchart illustrating a method of connecting a memory cartridge to a server system according to an example.

### DETAILED DESCRIPTION

Memory cartridges are removably inserted into slots of a chassis such as a server system. The memory cartridges may include dual inline memory modules (DIMMS) to communicate with the server system when inserted into the slots of the chassis. The DIMMS, for example, may store data and enable a user access to the data. Increased demands on server systems may include an increase in the amount of memory desired. Such increased demands may require more DIMMS, larger server systems and/or more space to install the server systems. Thus, the size of the server systems and/or space needed may increase the costs and space requirements for server systems.

In examples, a memory cartridge includes a first printed circuit board and a second printed circuit board. The first printed circuit board includes a first set of dual inline memory module (DIMM) connectors. The first set of DIMM connectors receive a first set of dual inline memory modules (DIMMS). The second printed circuit board includes a second set of DIMM connectors. The second printed circuit board receives a second set of DIMMS. The first printed circuit board and the second printed circuit board are movably connected to each other. The movable connection enables the first printed circuit board and the second printed circuit board to fold over each other in a closed state and unfold away from each other in an open state. Further, the amount of DIMMS that attach to each one of the first and second printed circuit boards may be increased. Additionally, multiple memory cartridges may be installed in a single slot of the chassis. Alternatively, the size of the slot may be reduced to receive the memory cartridge. Thus, the size and/or amount of space needed to install the server system having an increased amount of memory may be reduced.

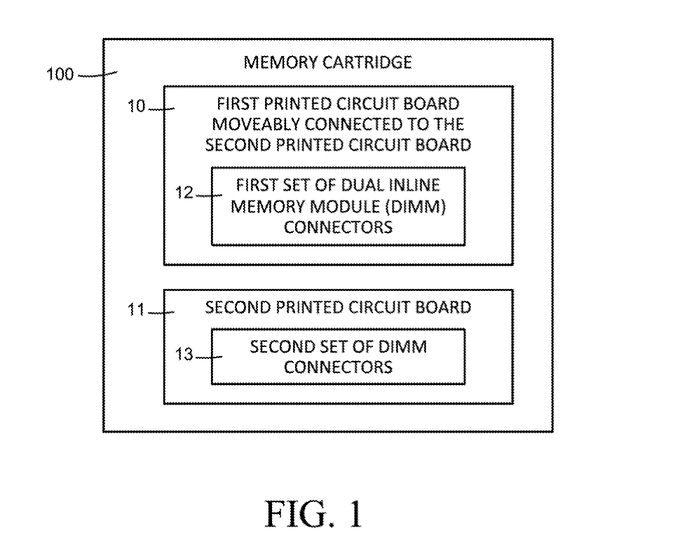

FIG. 1 is a block diagram illustrating a memory cartridge according to an example. Referring to FIG. 1, a memory cartridge 100 includes a first printed circuit board 10 and a second printed circuit board 11. The first printed circuit board 10 includes a first set of dual inline memory module (DIMM) connectors 12. The first set of DIMM connectors 12 receive a first set of dual inline memory modules (DIMMS). The second printed circuit board 11 includes a second set of DIMM connectors 13. The second set of DIMM connectors 13 receives a second set of DIMMS. The first printed circuit board 10 and the second printed circuit board 11 are movably connected to each other. The movable connection enables the first printed circuit board 10 and the second printed circuit board 11 to fold over each other in a closed state. For example, in a closed state, the memory cartridge 100 may be inserted into a slot of the chassis. Additionally, the movable connection enables the first printed circuit, board 10 and the second printed circuit board 11 to unfold away from each other in an open state. For example, in the open state, DIMMS and/or other components of the memory cartridge 100 may be accessible to be serviced and/or exchanged.

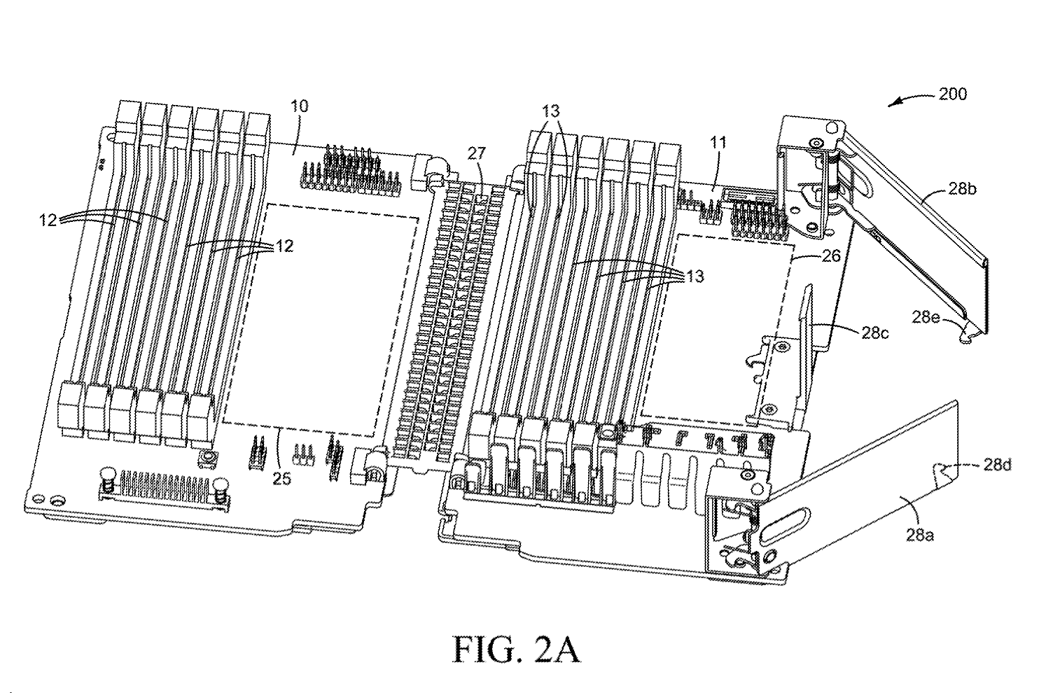

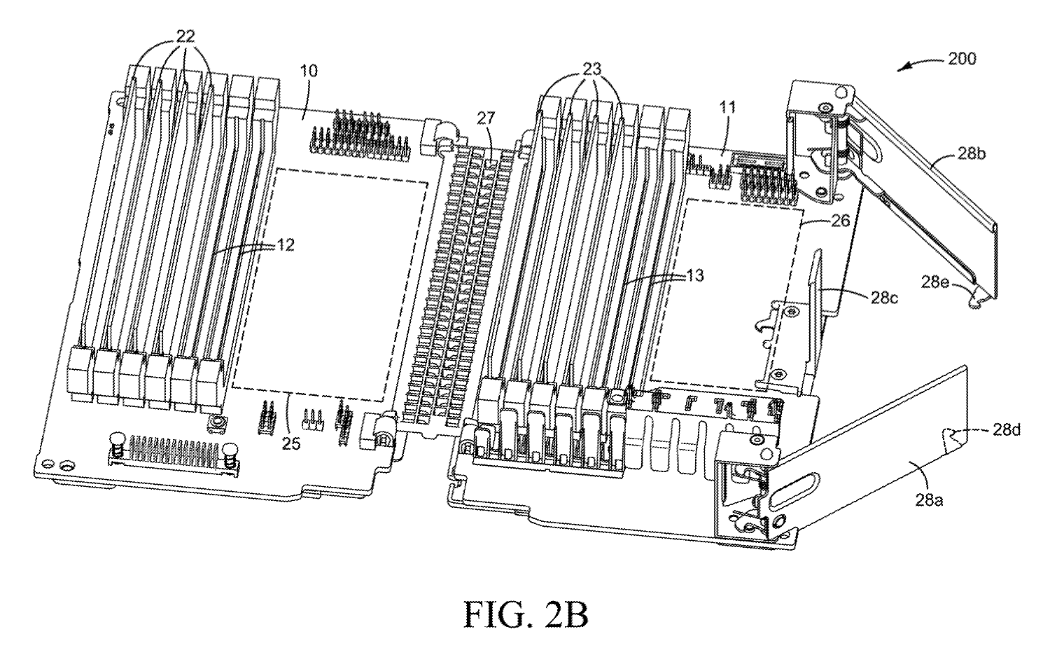

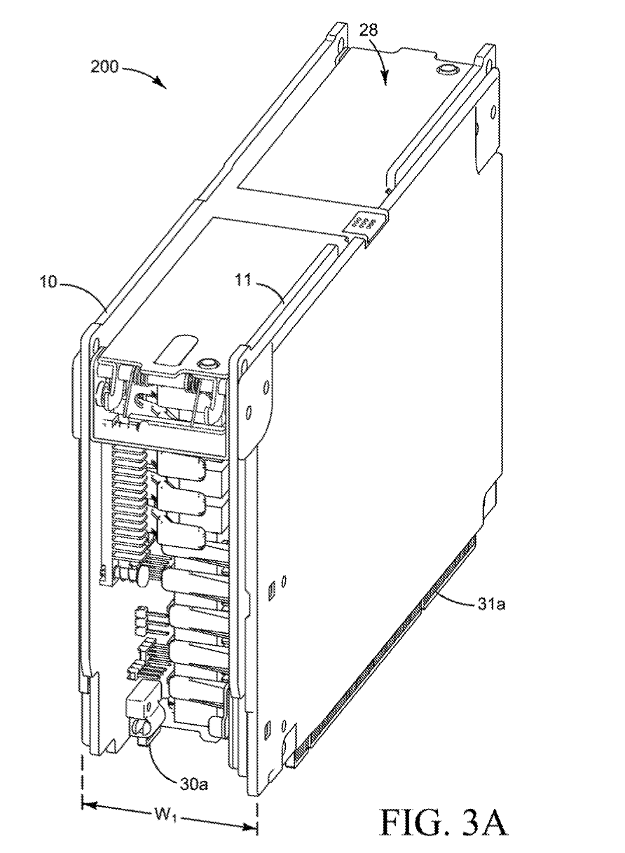

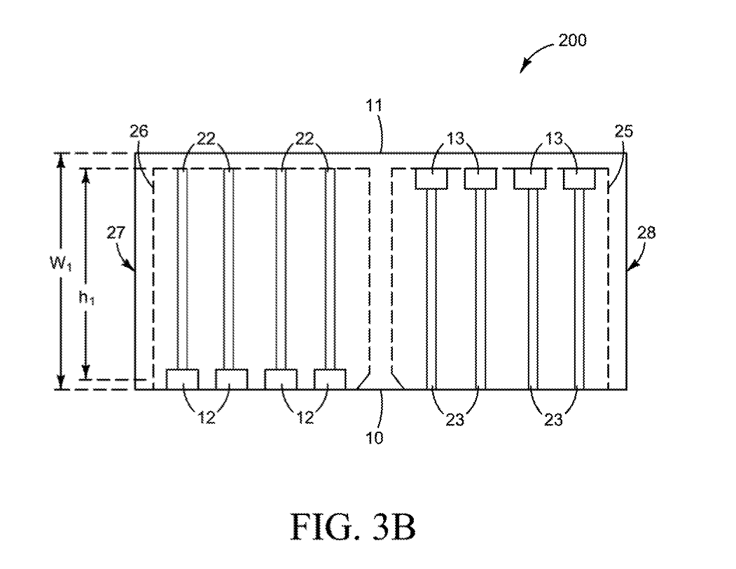

FIG. 2A is a perspective view illustrating a memory cartridge in an open state without DIMMS installed thereon according to an example. FIG. 2B is a perspective view illustrating a memory cartridge in an open state with DIMMS installed thereon according to an example. FIG. 3A is a perspective view illustrating the memory cartridge of FIG. 2B in a closed state according to an example. FIG. 3B is a cross-sectional view of the memory cartridge of FIG. 3A according to an example. In some examples, a memory cartridge 200 includes the first printed circuit board 10 and the second printed circuit board 11 as previously discussed with respect to the memory cartridge 100 of FIG. 1. Referring to FIGS. 2A-3B, in some examples, the memory cartridge 200 may also include a first DIMM receiving region 25, a second DIMM receiving region 26, a hinge member 27, and a latch device 28.

Referring to FIGS. 2A-3B, in some examples, the first printed circuit board 10 includes a first set of DIMM connectors 12. The first set of DIMM connectors 12 receive a first set of DIMMS 22. The second printed circuit board 11 includes a second set of DIMM connectors 13. The second printed circuit board 11 receives a second set of DIMMS 23. The first printed circuit board 10 and the second printed circuit board 11 are movably connected to each other. For example, the hinge member 27 may movably couple the first printed circuit board 10 and the second printed circuit board 11 to each other. That is, the first and second printed circuit boards 10 and 11 may fold over each other.

Referring to FIGS. 2A-3B, in some examples, the first printed circuit board 10 and the second printed circuit board 11 may fold over each other in a closed state (FIG. 3A). For example, the first set of DIMMS 22 and the second set of DIMMS 23 may be adjacent to each other in a direction parallel to respective planar surfaces of the first printed circuit board 10 and the second printed circuit board 11 in the closed state as illustrated in FIG. 3B. Additionally, the first printed circuit board 10 and the second printed circuit board 11 may unfold away from each other in an open state (FIGS. 2A and 2B). For example, the first printed circuit board 10 and the second printed circuit board 11 may be in a substantially same plane in the open state.

Referring to FIGS. 2A-3B, in some examples, the first DIMM receiving region 25 is formed between the first printed circuit board 10 and the second printed circuit board 11 in the closed state. The first DIMM receiving region 25 is also formed adjacent to the first set of DIMMS 22 to receive the second set of DIMMS 23 and the second set of DIMM connectors 13. That is, in the closed state, the second set of DIMMS 23 and the second set of DIMM connectors 13 occupy a space which is the first DIMM receiving region 25. The second DIMM receiving region 26 is formed between the first printed circuit board 10 and the second printed circuit board 11 in the closed state. The second DIMM receiving region 26 is also adjacent to the second set of DIMMS 23 to receive the first set of DIMMS 22 and the first set of DIMM connectors 12. That is, in the closed state, the first set of DIMMS 22 and the first set of DIMM connectors 12 occupy a space which is the second DIMM receiving region 26.

Referring to FIGS. 2A-3B, in some examples, the first printed circuit board 10 and the second printed circuit board 11 fold over each other in the closed state to form a modular housing to insert into a chassis of an electrical system. In some examples, a width w₁ of the modular housing to insert into the chassis is less than 120% of a height h₁ of a respective DIMM attached thereto. Thus, in some examples, multiple memory cartridges 200 may be installed in a single slot of the chassis. Alternatively, the size of the slot may be reduced to receive the memory cartridge 200.

Referring to FIGS. 2A-3B, in some examples, the first printed circuit board 10 also includes a first edge connector 30a to electrically connect the first set of DIMMS 22 to the electrical system when the modular housing is inserted into the chassis. The second printed circuit board 11 also includes a second edge connector 31a to electrically connect the second set of DIMMS 23 to the electrical system when the modular housing is inserted into the chassis.

Referring to FIGS. 2A-3, in some examples, the latch device 28 (28a, 28b, 28c, 28d, and 28e collectively 28) may be disposed proximate to one end of the second printed circuit board 11 opposite another end of the second printed circuit board 11 coupled to the first printed circuit board 10. The latch device 28 may latch the first printed circuit board 10 to the second printed circuit board 11 in the closed state. In some examples, the latch device 28 may include a first latch door 28a, a second latch door 28b, and an intermediate latch member 28c. The first latch door 28a may include a first latch member 28d. The second latch door 28b may include a second latch member 28e. In the closed state, the first and second printed circuit boards 10 and 11 are folded over each other. That is, the first and second latch doors 28a and 28b move toward the intermediate latch member 28c to enable the first and second latch members 28d and 28e to engage the intermediate latch member 28c. In doing so, the latch device 28 latches the first printed circuit board 10 and the second printed circuit board 11.

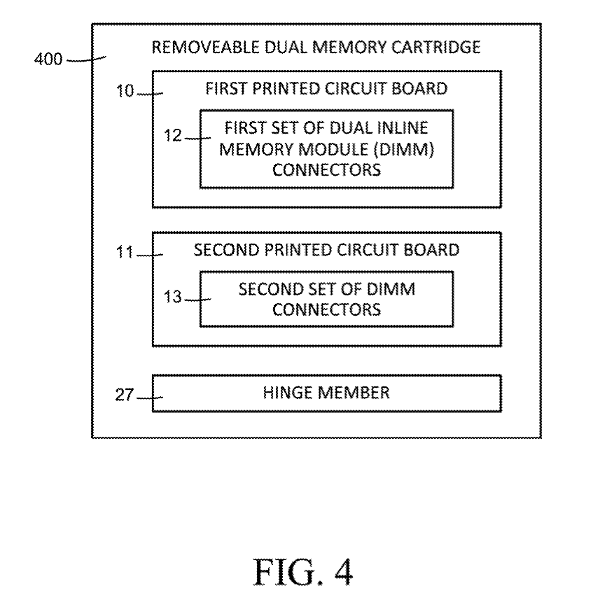

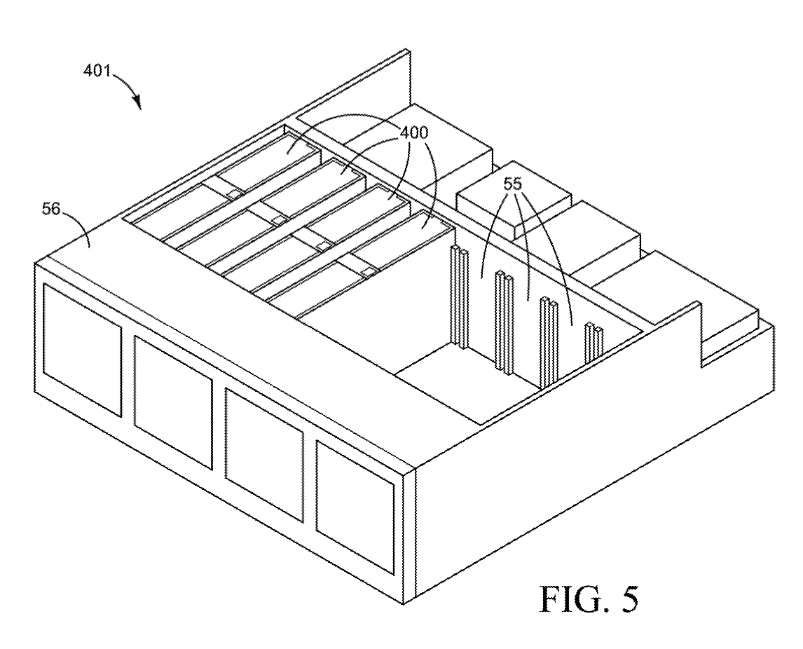

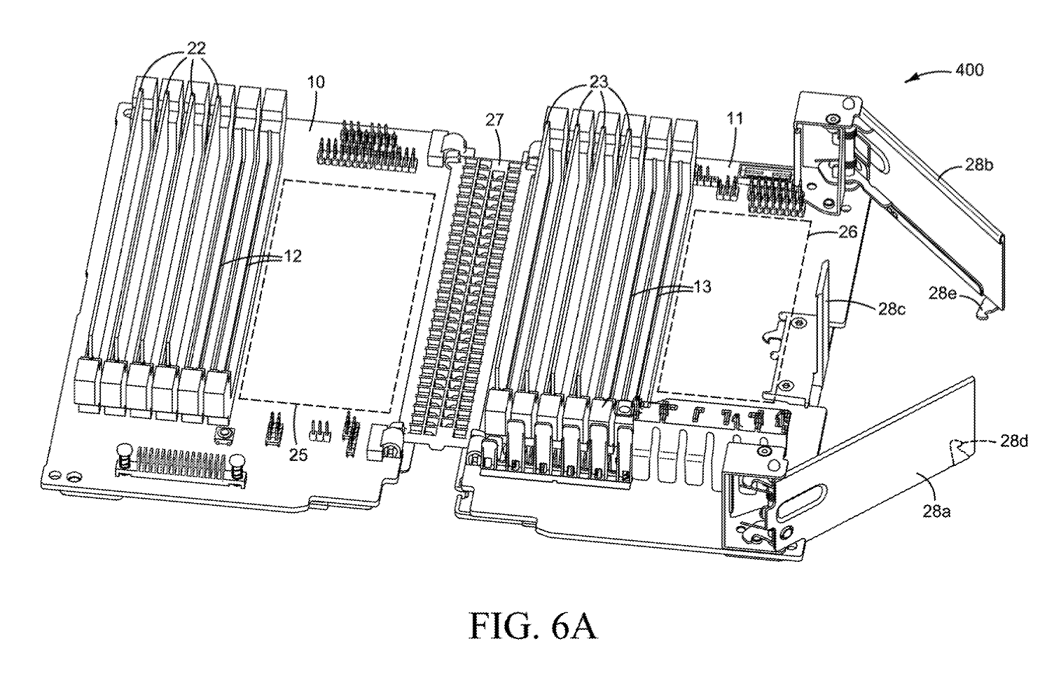

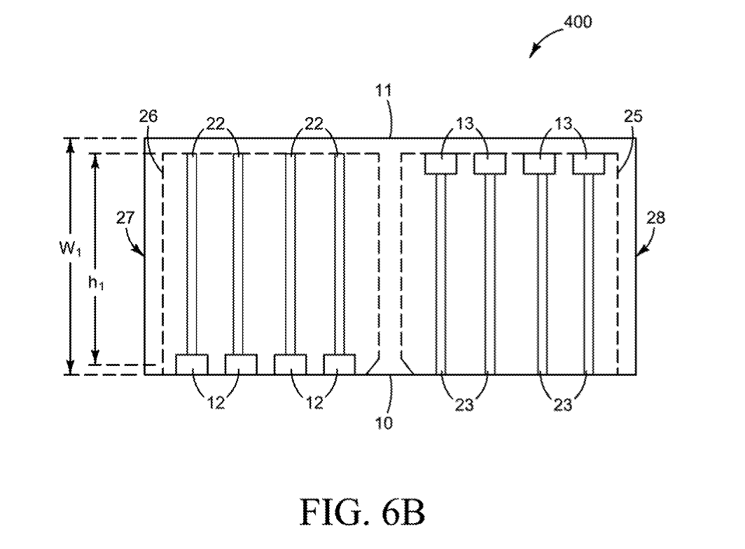

FIG. 4 is a block diagram illustrating a removable dual memory cartridge according to an example. FIG. 5 is a perspective view illustrating a server system with a plurality of removable dual memory cartridges installed therein according to an example. FIG. 6A is a perspective view illustrating a respective removable dual memory cartridge of FIG. 4 according to an example. FIG. 6B is a cross-sectional of the respective removable dual memory cartridge of FIG. 6A according to an example. The removable dual memory cartridge 400 is usable with a server system 401. Referring to FIGS. 4-6B, in some examples, the dual memory cartridge 400 includes a first printed circuit board 10, a second printed circuit board 11, and a hinge member 27. The first printed circuit board 10 includes a first set of DIMM connectors 12 to receive a first set of DIMMS 22. The second printed circuit board 11 includes a second set of DIMM connectors 13 to receive a second set of DIMMS 23. The hinge member 27 movably couples the first printed circuit board 10 and the second printed circuit board to each other 11.

The hinge member 27 enables the first printed circuit board 10 and the second printed circuit board 11 to fold over each other in a closed, state. Additionally, the hinge member 27 enables the first printed circuit board 10 and the second printed circuit board 11 to unfold away from each other in an open state. In some examples, the first printed circuit board 10 and the second printed circuit board 11 are in a substantially same plane in the open state. The first printed circuit board 10 and the second printed circuit board 11 fold over each other in the closed state to form a modular housing to insert into a slot 55 of a server chassis 56 of the server system 401. In some examples, the first set of DIMMS 22 and the second set of DIMMS 23 are adjacent to each other in a direction parallel to planar surfaces of the first and second printed circuit boards 10 and 11 in the closed state.

Referring to FIGS. 4-6B, in some examples, the first DIMM receiving region 25 is formed between the first printed circuit board 10 and the second printed circuit board 11 in the closed state. The first DIMM receiving region 25 is also formed adjacent to the first set of DIMMS 22 to receive the second set of DIMMS 23 and the second set of DIMM connectors 13. The second DIMM receiving region 26 is formed between the first printed circuit board 10 and the second printed circuit board 11 in the closed state. The second DIMM receiving region 26 is also adjacent to the second set of DIMMS 23 to receive the first set of DIMMS 22 and the first set of DIMM connectors 12. The first printed circuit board 10 and the second printed circuit board 11 fold over each other in the closed state to form a modular housing to insert into a chassis 56 of the server system 401. In some examples, a width w₁ of the modular housing to insert into the chassis 56 is less than 120% of a height h₁ of a respective DIMM attached thereto. Thus, in some examples, multiple memory cartridges 400 may be installed in a single slot 55 of the chassis 56. Alternatively, the size of the slot 55 may be reduced to receive the memory cartridge 400. For example, in some examples, a height h₁ of a respective DIMM may be 1.75 inches and a width of the modular housing may be 2.00 inches.

Referring to FIGS. 4-6B, in some examples, the first printed circuit board 10 also includes a first edge connector 30a to electrically connect the first set of DIMMS 22 to the server system 401 when the modular housing is inserted into the chassis 56. The second printed circuit board 11 also includes a second edge connector 31a to electrically connect the second set of DIMMS 23 to the server system 401 when the modular housing is inserted into the chassis 56.

Referring to FIGS. 4-6B, in some examples, the latch device 28 may be disposed proximate to one end of the second printed circuit board 11 opposite another end of the second printed circuit board 11 coupled to the first printed circuit board 10. The latch device 28 may latch the first printed circuit board 10 to the second printed circuit board 11 in the closed state. In some examples, the latch device may include a first latch door 28a, a second latch door 28b, and an intermediate latch member 26e. The first latch door 28a may include a first latch member 28d. The second latch door 28b may include a second latch member 28e, In the closed state, the first and second printed circuit boards 10 and 11 are folded over each other. That is, the first and second latch doors 28a and 28b move toward the intermediate latch member 28c to enable the first and second latch members 28d and 28e to engage the intermediate latch member 28c. In doing so, the latch device 28 latches the first printed circuit board 10 and the second printed circuit board 11.

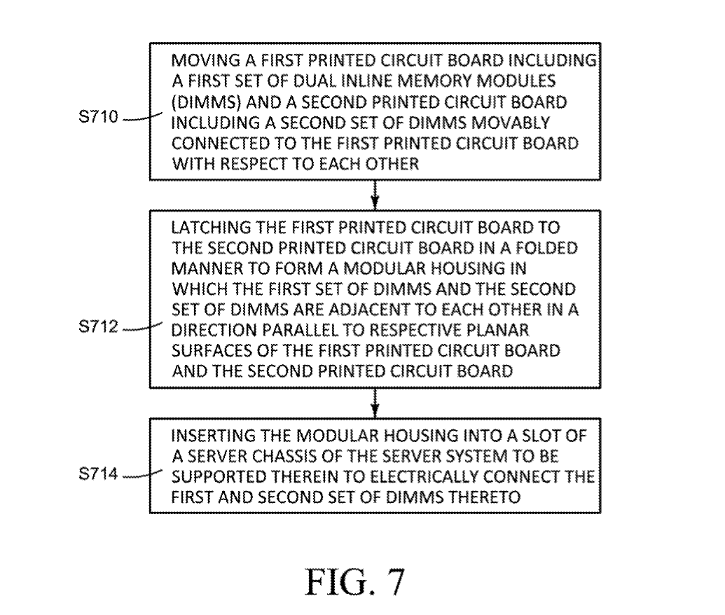

FIG. 7 is a flowchart illustrating a method of connecting a memory cartridge to a server system according to an example. In some examples, the modules, assemblies, and the like, previously discussed with respect to FIGS. 1-6B may be used to implement the method of FIG. 7. Referring to FIG. 7, in block S710, a first printed circuit board including a first set of dual inline memory modules (DIMMS) and a second printed circuit board including a second set of DIMMs movably connected to the first printed circuit board is moved with respect to each other. In block S712, the first printed circuit board is latched to the second printed circuit board in a folded manner to form a modular housing in which the first set of DIMMS and the second set of DIMMS are adjacent to each other in a direction parallel to respective planar surfaces of the first printed circuit board and the second printed circuit board. In block S714, the modular housing is inserted into a slot of a server chassis of the server system to be supported therein and electrically connect the first and second set of DIMMS thereto.

In some examples, the method may also include removing the modular housing from the slot of the server chassis to electrically disconnect the first and second set of DIMMS from the server system. The method may also include unlatching the first printed circuit board from the second printed circuit board. The method may also include moving the first printed circuit board and the second printed circuit board with respect to each other to place the memory cartridge in an open state in which the first printed circuit board and the second printed circuit board are in a substantially same plane.

It is to be understood that the flowchart of FIG. 7 illustrates architecture, functionality, and/or operation of examples of the present disclosure. If embodied in software, each block may represent a module, segment, or portion of code that includes one or more executable instructions to implement the specified logical function(s). If embodied in hardware, each block may represent a circuit or a number of interconnected circuits to implement the specified logical function(s). Although the flowchart of FIG. 7 illustrates a specific order of execution, the order of execution may differ from that which is depicted. For example, the order of execution of two or more blocks may be rearranged relative to the order illustrated. Also, two or more blocks illustrated in succession in FIG. 7 may be executed concurrently or with partial concurrence. All such variations are within the scope of the present disclosure.

The present disclosure has been described using non-limiting detailed descriptions of examples thereof that are not intended to limit the scope of the general inventive concept. It should be understood that features and/or operations described with respect to one example may be used with other examples and that not all examples have all of the features and/or operations illustrated in a particular figure or described with respect to one of the examples. Variations of examples described will occur to persons of the art. Furthermore, the terms “comprise,” “include,” “have” and their conjugates, shall mean, when used in the disclosure and/or claims, “including but not necessarily limited to.”

It is noted that some of the above described examples may include structure, acts or details of structures and acts that may not be essential to the general inventive concept and which are described for illustrative purposes. Structure and acts described herein are replaceable by equivalents, which perform the same function, even if the structure or acts are different, as known in the art. Therefore, the scope of the general inventive concept is limited only by the elements and limitations as used in the claims.

What is claimed is:

1. A memory cartridge, comprising:
a first printed circuit board including a first set of dual inline memory module (DIMM) connectors to receive a first set of dual inline memory modules (DIMMS); and
a second printed circuit board including a second set of DIMM connectors to receive a second set of DIMMS, the first printed circuit board and the second printed circuit board are movably connected to each other to enable the first printed circuit board and the second printed circuit board to fold over each other in a closed state and unfold away from each other in an open state.

2. The memory cartridge of claim 1, further comprising:
a hinge member to movably couple the first printed circuit board and the second printed circuit board to each other. 3, The memory cartridge of claim 1, further comprising:
a latch device disposed proximate to one end of the second printed circuit board opposite another end of the second printed circuit board coupled to the first printed circuit board, the latch device to latch the first printed circuit board to the second printed circuit board in the closed state.

4. The memory cartridge of claim 1, wherein the first printed circuit board and the second printed circuit board are in a substantially same plane in the open state.

5. The memory cartridge of claim 1, wherein the first set of DIMMS and the second set of DIMMS are adjacent to each other in a direction parallel to respective planar surfaces of the first printed circuit board and the second printed circuit board in the closed state.

6. The memory cartridge of claim 1, further comprising:
a first DIMM receiving region formed between the first printed circuit board and the second printed circuit board in the dosed state, and adjacent to the first set of DIMMS to receive the second set of DIMMS and the second set of DIMM connectors; and
a second DIMM receiving region formed between the first printed circuit board and the second printed circuit board in the closed state, and adjacent to the second set of DIMMS to receive the first set of DIMMS and the first set of DIMM connectors.

7. The memory cartridge of to claim 1, wherein the first printed circuit board and the second printed circuit board fold over each other in the closed state to form a modular housing to insert into a chassis of an electrical system.

8. The memory cartridge of claim 7, wherein the first printed circuit board further includes a first edge connector and the second printed circuit board further includes a second edge connector, the first and second edge connectors to electrically connect the first and second set of DIMMS to the electrical system when, the modular housing is inserted into the chassis.

9. The memory cartridge of claim 7, wherein a width of the modular housing to insert into the chassis is less than 120% of a height of a respective DIMM attached thereto.

10. A removable dual memory cartridge usable with a server system, the dual memory cartridge comprising:
a first printed circuit board including a first set of dual inline memory module (DIMM) connectors to receive a first set of dual inline memory modules (DIMMS);
a second printed circuit board including a second set of DIMM connectors to receive a second set of DIMMS; and
a hinge member to movably couple the first printed circuit board and the second printed circuit board to each other to enable the first printed circuit board and the second printed circuit board to fold over each other in a closed state and unfold away from each other in an open state; and
wherein the first printed circuit board and the second printed circuit board fold over each other in the closed state to form a modular housing to insert into a slot of a server chassis of the server system.

11. The removable dual memory cartridge of claim 10, further comprising:
a latch device disposed proximate to one end of the second printed circuit board opposite another end of the second printed circuit board coupled to the first printed circuit board, the latch device to latch the first printed circuit board to the second printed circuit board in the closed state.

12. The removable dual memory cartridge of claim 10, wherein the first printed circuit board and the second printed circuit board are substantially in a same plane in the open state, and the first set of DIMMS and the second set of DIMMS are adjacent to each other in a direction parallel to planar surfaces of the first and second printed circuit boards in the closed state.

13. The removable dual memory cartridge of claim 10, further comprising:
a first DIMM receiving region formed between the first printed circuit board and the second printed circuit board in the closed state, and adjacent to the first set of DIMMS to receive the second set of LIMNS and the second set of DIMM connectors; and
a second DIMM receiving region formed between the first printed circuit board and the second printed circuit board in the dosed state, and adjacent to the second set of DIMMS to receive the first set of DIMMS and the first set of DIMM connectors.

14. A method of connecting a memory cartridge to a server system, the method comprising:
moving a first printed circuit board including a first set of dual inline memory modules (DIMMS) and a second printed circuit board including a second set of DIMMS movably connected to the first printed circuit board with respect to each other;
latching the first printed circuit board to the second printed circuit board in a folded manner to form a modular housing in which the first set of DIMMS and the second set of DIMMS are adjacent to each other in a direction parallel to respective planar surfaces of the first printed circuit board and the second printed circuit board; and
inserting the modular housing into a slot of a server chassis of the server system to be supported therein to electrically connect the first and second set of DIMMS thereto.

15. The method of claim 14, further comprising:
removing the modular housing from the slot of the server chassis to electrically disconnect the first and second set of DIMMS from the server system;
unlatching the first printed circuit board from the second printed circuit board; and
moving the first printed circuit board and the second printed circuit board with respect to each other to place the memory cartridge in an open state in which the first printed circuit board and the second printed circuit board are in a substantially same plane.
